(19) United States
(12) Patent Application Publication
(10) Pub. No.: US 2026/0279052 A1
(43) Pub. Date: Sep. 17, 2026

(54) TIME SYNCHRONIZATION METHOD AND MANUFACTURING APPARATUS

(71) Applicant: SCREEN Holdings Co., Ltd., Kyoto (JP)

(72) Inventor: Kazuna SAWADA, Kyoto-shi, Kyoto (JP)

(21) Appl. No.: 18/871,950

(22) PCT Filed: May 16, 2023
(86) PCT No.: PCT/JP2023/018343

§ 371 Date: Dec. 5, 2024

(30) Foreign Application Priority Data
Jun. 28, 2022 (JP) 2022-103548

(51) Int. Cl. G06V 20/40; G06V 10/12

(52) U.S. Cl. CPC G06V 20/44; G06V 10/12; G06V 2201/06

(57) ABSTRACT

A time synchronization method for synchronizing times attached to a plurality of captured image data pieces includes a) imaging an object to be imaged by a plurality of cameras to acquire a captured image data piece for each camera, b) detecting, for each captured image data piece, an event image that has captured a predetermined event from the captured image data piece, and c) synchronizing times attached to the plurality of captured image data pieces in accordance with times attached to the event images detected for the captured image data pieces. Accordingly, it is possible to synchronize the times among the plurality of captured image data pieces without communication with an external network.

### TECHNICAL FIELD

The present invention relates to a time synchronization method for synchronizing times attached to a plurality of captured image data pieces, and also relates to a manufacturing apparatus.

### BACKGROUND ART

There may be situations in which a plurality of image capturing devices capture images of a device to be controlled, and operations of the device to be controlled are controlled based on captured image data pieces. In this case, it becomes necessary to synchronize times among the captured image data pieces obtained by each image capturing device.

For example, Patent Literature (PTL) 1 describes an image recorder that is configured to record image data acquired by a camera-extension-unit processor in time series in association with information about the time of acquisition of the image data and transmit the image data and the information about the time to a CPU unit in response to an instruction received from the CPU unit. The aforementioned configuration allows high-precision time synchronization with device records about image data captured by cameras.

As another method for synchronizing times among captured image data pieces, for example, a method as disclosed in Non-Patent Literature (NPTL) 1 is also known. NPTL 1 describes synchronizing times among devices connected to an external network.

### CITATION LIST

### Patent Literature

PTL 1: Japanese Patent Application Laid-Open No. 2020-134985

### Non-Patent Literature

NPTL 1:“IEEE Standard for a Precision Clock Synchronization Protocol for Networked Measurement and Control Systems,” IEEE Std, 1588-2008

### SUMMARY OF INVENTION

### Technical Problem

However, it is difficult, for devices that need to be operated while being isolated from an external network for the purpose of security measures, to synchronize times among a plurality of captured image data pieces by communication with an external network. In the case where the devices are provided with a time server function, problems arise such as additional installation costs and limited installation places depending on free spaces within the devices.

The present invention has been made in light of such circumstances, and it is an object of the present invention to provide a technique for synchronizing times among a plurality of captured image data pieces without communication with an external network.

### Solution to Problem

To solve the problem described above, a first aspect of the present application is a time synchronization method for synchronizing times attached to a plurality of captured image data pieces. The time synchronization method includes a) imaging an object to be imaged by a plurality of cameras to acquire a captured image data piece for each of the cameras, the captured image data piece being included in the plurality of captured image data pieces, b) detecting, for each of the captured image data pieces, an event image that has captured a predetermined event from the captured image data piece, and c) synchronizing times attached to the plurality of captured image data pieces in accordance with times attached to the event images detected for the plurality of captured image data pieces.

A second aspect of the present application is the time synchronization method according to the first aspect, in which the event corresponds to a situation in which a predetermined portion of the object to be imaged has passed through a predetermined location in an imaging region captured by the plurality of cameras.

A third aspect of the present application is the time synchronization method according to the second aspect, in which in the operation b), the event image is detected based on a reference image that serves as a reference during detection.

A fourth aspect of the present application is the time synchronization method according to the first aspect, in which the event corresponds to a situation in which luminance of a predetermined region in the captured image data piece has reached a predetermined threshold value.

A fifth aspect of the present application is the time synchronization method according to the fourth aspect, in which the operation a) includes emitting light to the imaging region captured by the plurality of cameras with predetermined timing during imaging of the object to be imaged by the plurality of cameras.

A sixth aspect of the present application is the time synchronization method according to the fourth or fifth aspect, in which the operation b) includes when one of the captured image data pieces includes one captured image that has captured the event, detecting the one captured image as the event image, and when one of the captured image data pieces includes a plurality of captured images that have captured the event, detecting one of the plurality of captured images as the event image in accordance with the luminance of each of the plurality of captured images.

A seventh aspect of the present application is the time synchronization method according to any one of the first to fifth aspects, in which the operation b) includes when one of the captured image data pieces includes one captured image that has captured the event, detecting the one captured image as the event image, and when one of the captured image data pieces includes a plurality of captured images that have captured the event, detecting one of the plurality of captured images as the event image in accordance with times attached to the plurality of captured images.

An eighth aspect of the present application is the time synchronization method according to any one of the first to seventh aspects, in which the captured image data pieces are moving images, and the event image is a frame included in the moving images.

A ninth aspect of the present application is the time synchronization method according to any one of the first to eighth aspects, in which the operations a), b), and c) are repeatedly performed at a predetermined time interval.

A tenth aspect of the present application is a manufacturing method for performing processing based on a plurality of captured image data pieces. The manufacturing method includes a plurality of cameras that image an object to be imaged, and a controller. The controller a) causes the plurality of cameras to image the object to be imaged, to acquire a captured image data piece for each of the cameras, the captured image data piece being included in the plurality of captured image data pieces, b) detecting, for each of the captured image data pieces, an event image that has captured a predetermined event from a plurality of captured images included in the captured image data piece, and c) synchronizing times attached to the plurality of captured image data pieces in accordance with times attached to the event images detected for the captured image data pieces.

### Advantageous Effects of Invention

According to the first to tenth aspects of the present application, it is possible to synchronize times among the plurality of captured image data pieces without communication with an external network.

In particular, according to the second aspect of the present application, it is possible to synchronize times among the plurality of captured image data pieces in accordance with a predetermined operation of the object to be imaged.

In particular, according to the fourth aspect of the present application, it is possible to synchronize times among the plurality of captured image data pieces in accordance with a change in the luminance of a predetermined region in the captured image data pieces.

In particular, according to the sixth aspect of the present application, it is possible to more precisely synchronize times among the plurality of captured image data pieces.

In particular, according to the seventh aspect of the present application, it is possible to more precisely synchronize times among the plurality of captured image data pieces.

In particular, according to the ninth aspect of the present application, it is possible to continually synchronize times among the plurality of captured image data pieces.

### BRIEF DESCRIPTION OF DRAWINGS

FIG. 1 is a plan view of a substrate processing apparatus.

FIG. 2 is a longitudinal sectional view of a processing unit.

FIG. 3 is a diagram conceptually showing image capture by cameras.

FIG. 4 is a diagram conceptually showing image capture by the cameras.

FIG. 5 is a block diagram showing connection between a computer and each constituent element of a processing unit.

FIG. 6 is a flowchart showing a procedure of substrate processing.

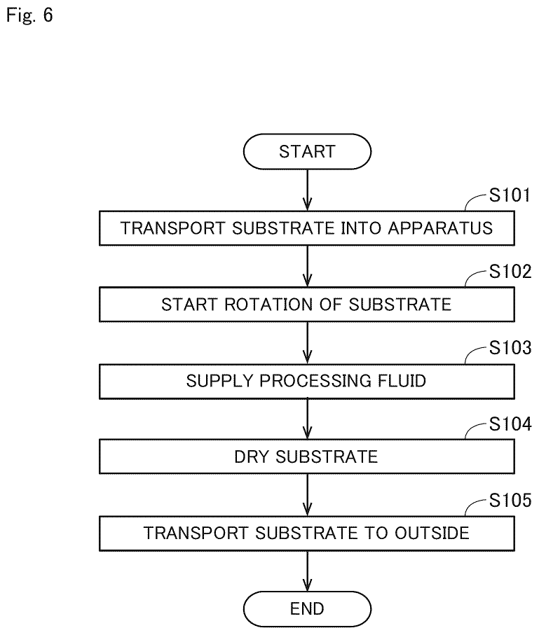

FIG. 7 is a flowchart showing a procedure of time synchronization processing.

FIG. 8 is a flowchart showing another procedure of the time synchronization processing.

FIG. 9 is a diagram conceptually showing configurations of moving images.

FIG. 10 is a diagram conceptually showing the configurations of the moving images after time synchronization.

### DESCRIPTION OF EMBODIMENT

Embodiments of the present invention are described hereinafter in detail with reference to the drawings.

### 1. Overall Configuration of Substrate Processing Apparatus

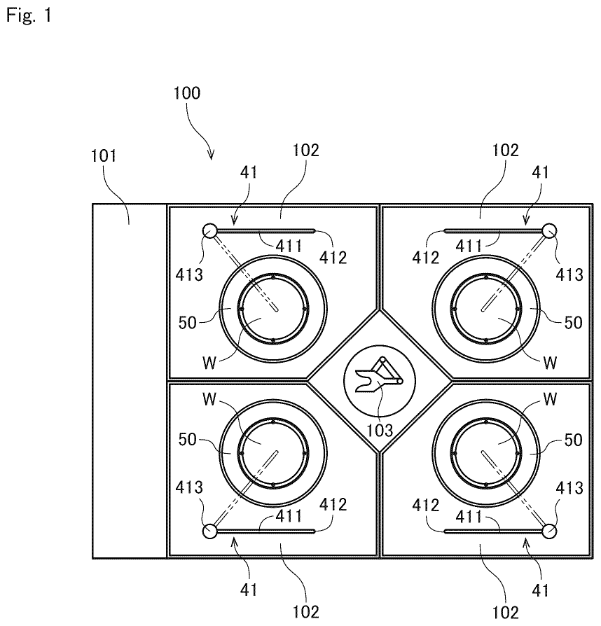

FIG. 1 is a plan view of a substrate processing apparatus 100 as one example of a manufacturing apparatus according to the present invention. The substrate processing apparatus 100 is an apparatus that, in the process of manufacturing semiconductor wafers, processes surfaces of disk-like substrates W (semiconductor wafers) by supplying a processing fluid to the surfaces of the substrates W. As shown in FIG. 1, the substrate processing apparatus 100 includes an indexer 101, a plurality of processing units 102, and a main transport robot 103.

The indexer 101 is a part for transporting substrates W that have not been processed from the outside into the apparatus and transporting processed substrates W to the outside of the apparatus. The indexer 101 includes a plurality of carriers arranged to house a plurality of substrates W. The indexer 101 also includes a transfer robot which is not shown. The transfer robot transfers substrates W between the carriers of the indexer 101 and the processing units 102 or the main transport robot 103.

The processing units 102 are so-called sheet-fed processing parts that process substrates W one by one. The processing units 102 are arranged around the main transport robot 103. In the present embodiment, three layers each including four processing units 102 arranged around the main transport robot 103 are laminated one above another in the height direction. That is, the substrate processing apparatus 100 according to the present embodiment includes a total of 12 processing unit 102. A plurality of substrates W are processed in parallel in each processing unit 102. The number of processing units 102 included in the substrate processing apparatus 100 is not limited to 12 and may, for example, be one, four, eight, or 24.

The main transport robot 103 is a mechanism for transporting substrates W between the indexer 101 and the processing units 102. For example, the main transport robot 103 may include a hand that holds substrates W and an arm that moves the hand. The main transport robot 103 takes out substrates W that have not been processed from the indexer 101 and transports the substrates W to the processing units 102. When the processing of substrates W in the processing units 102 is completed, the main transport robot 103 takes out the processed substrates W from the processing units 102 and transports the processed substrates W to the indexer 101.

### 2. Configuration of Processing Units

Next, a detailed configuration of the processing units 102 is described. While the following description is given of one of the processing units 102 included in the substrate processing apparatus 100, the other processing units 102 also have equivalent configurations.

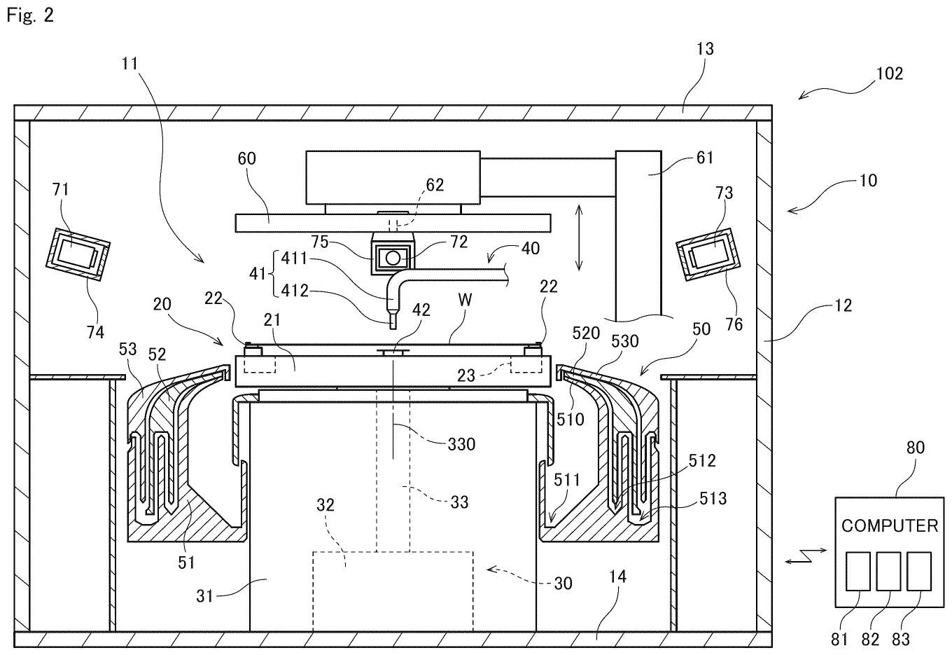

FIG. 2 is a longitudinal sectional view of one processing unit 102. As shown in FIG. 2, the processing unit 102 includes a chamber 10, a substrate holder 20, a rotation mechanism 30, a processing fluid supplier 40, a processing fluid collector 50, a barrier plate 60, a first camera 71, a second camera 72, a third camera 73, and a computer 80.

The chamber 10 is a casing that includes a processing space 11 for processing a substrate W. The chamber 10 has a side wall 12 that surrounds the lateral side of the processing space 11, a top plate 13 that covers the top of the processing space 11, and a bottom plate 14 that covers the bottom of the processing space 11. The substrate holder 20, the rotation mechanism 30, the processing fluid supplier 40, the processing fluid collector 50, the barrier plate 60, the first camera 71, the second camera 72, and the third camera 73 are housed inside the chamber 10. Part of the side wall 12 has a transport entrance for transporting a substrate W into and out of the chamber 10, and a shutter that opens and closes the transport entrance.

The substrate holder 20 is a mechanism for holding a substrate W horizontally (in a position in which the normal faces a vertical direction) inside the chamber 10. As shown in FIG. 2, the substrate holder 20 includes a disk-like spin base 21 and a plurality of chuck pins 22. The chuck pins 22 are provided at equiangular intervals along the outer periphery of the upper surface of the spin base 21. A substrate W is held by the chuck pins 22, with its to-be-processed surface on which the pattern is formed facing upward. Each chuck pin 22 comes in contact with the lower surface of the peripheral portion of the substrate W and the outer peripheral end face of the substrate W and supports the substrate W at a position spaced above from the upper surface of the spin base 21 with slight clearance therebetween.

The spin base 21 includes a chuck-pin switching mechanism 23 for switching the positions of the chuck pins 22. The chuck-pin switching mechanism 23 switches the chuck pins 22 between a chucking position at which a substrate W is held and a de-chucking position at which hold of a substrate W is released.

The rotation mechanism 30 is a mechanism for rotating the substrate holder 20. The rotation mechanism 30 is housed inside a motor cover 31 provided below the spin base 21. As indicated by broken lines in FIG. 2, the rotation mechanism 30 includes a spin motor 32 and a support shaft 33. The support shaft 33 extends in the vertical direction and has a lower end connected to the spin motor 32 and an upper end fixed to the center of the spin base 21. When the spin motor 32 is driven, the support shaft 33 rotates about the shaft center 330. The substrate holder 20 and the substrate W held by the substrate holder 20 also rotate together with the support shaft 33 about the shaft center 330.

The processing fluid supplier 40 is a mechanism for supplying a processing fluid to the upper surface of a substrate W held by the substrate holder 20. The processing fluid supplier 40 includes a top nozzle 41 and a bottom nozzle 42. As shown in FIGS. 1 and 2, the top nozzle 41 includes a nozzle arm 411, a nozzle head 412 provided at the tip of the nozzle arm 411, and a nozzle motor 413. The nozzle arm 411 is driven by the nozzle motor 413 and rotates in the horizontal direction about the root end of the nozzle arm 411. This makes the nozzle head 412 movable between a processing position located above a substrate W held by the substrate holder 20 (position indicated by chain double-dashed lines in FIG. 1) and a retracted position located outward of the processing fluid collector 50 (position indicated by solid lines in FIG. 1).

The nozzle head 412 is connected to a fluid supplier (not shown) for supplying a processing fluid. Examples of the processing fluid that is used include an SPM cleaning fluid (a mixed solution of sulfuric acid and a hydrogen peroxide solution), an SC-1 cleaning fluid (a mixed solution of aqueous ammonia, a hydrogen peroxide solution, and pure water), an SC-2 cleaning fluid (a mixed solution of hydrochloric acid, a hydrogen peroxide solution, and pure water), a DHF cleaning fluid (dilute hydrofluoric acid), and pure water (deionized water). When a valve of the fluid supplier is opened with the nozzle head 412 arranged at the processing position, the processing fluid supplied from the fluid supplier is ejected from the nozzle head 412 toward the upper surface of a substrate W held by the substrate holder 20.

The nozzle head 412 may be a so-called two-fluid nozzle that generates droplets by mixing a processing fluid and a pressurized gas and then ejects a mixed fluid of the droplets and a gas to a substrate W. Each processing unit 102 may include a plurality of top nozzles 41.

The bottom nozzle 42 is arranged inside a through hole provided in the center of the spin base 21. The bottom side nozzle 42 has an exhaust port that faces the lower surface of a substrate W held by the substrate holder 20. The bottom nozzle 42 is also connected to a fluid supplier for supplying a processing fluid. When the processing fluid is supplied from the fluid supplier to the bottom nozzle 42, the processing fluid is ejected from the bottom nozzle 42 toward the lower surface of a substrate W.

The processing fluid collector 50 is a part that collects a used processing fluid. As shown in FIG. 2, the processing fluid collector 50 includes an inner cup 51, an intermediate cup 52, and an outer cup 53. The inner cup 51, the intermediate cup 52, and the outer cup 538 can be moved up and down independently of one another between a raised position and a lowered position by an elevating mechanism, which is not shown, the raised position being a position at which the upper end portions of the cups are positioned above a substrate W, the lowered position being a position at which the upper end portions of the cups are positioned below a substrate W. In FIG. 2, the inner cup 51, the intermediate cup 52, and the outer cup 53 are all arranged at the lowered position.

The inner cup 51 includes a ring-shaped first guide plate 510 that encircles the surrounding of the substrate holder 20. The intermediate cup 52 includes a ring-shaped second guide plate 520 that is located outward and upward of the first guide plate 510. The outer cup 53 includes a ring-shaped third guide plate 530 that is located outward and upward of the second guide plate 520. The bottom of the inner cup 51 expands to under the intermediate cup 52 and the outer cup 53. This bottom has an upper surface in which a first drain groove 511, a second drain groove 512, and a third drain groove 513 are provided in order from the inside.

The processing fluid ejected from the top nozzle 41 and the bottom nozzle 42 of the processing fluid supplier 40 is supplied to a substrate W and then scattered outward by centrifugal force generated by rotation of the substrate W. Then, the processing fluid scattered from the substrate W is collected by one of the first guide plate 510, the second guide plate 520, and the third guide plate 530. In the case where the inner cup 51, the intermediate cup 52, and the outer cup 53 are all positioned at the raised position, the processing fluid scattered from the substrate W is collected by the first guide plate 510. The processing fluid collected by the first guide plate 510 is discharged through the first drain groove 511 to the outside of the processing unit 102. In the case where the inner cup 51 is positioned at the lowered position and the intermediate cup 52 and the outer cup 53 are positioned at the raised position, the processing fluid scattered from the substrate W is collected by the second guide plate 520. The processing fluid collected by the second guide plate 520 is discharged through the second drain groove 512 to the outside of the processing unit 102. In the case where the inner cup 51 and the intermediate cup 52 are positioned at the lowered position and the outer cup 53 is positioned at the raised position, the processing fluid scattered from the substrate W is collected by the third guide plate 530. The processing fluid collected by the third guide plate 530 is discharged through the third drain groove 513 to the outside of the processing unit 102.

In this way, the processing unit 102 includes a plurality of passages for discharging the processing fluid. Thus, the processing fluid supplied to the substrate W can be distinguished and collected depending on the type. Accordingly, other processing such as disposal or regeneration of a collected processing fluid can also be performed separately depending on the properties of the processing fluid.

The barrier plate 60 is a member for suppressing diffusion of a gas in the vicinity of the surface of a substrate W during some processing such as dry processing. The barrier plate 60 has a disk-like outside shape and is arranged horizontally above the substrate holder 20. As shown in FIG. 2, the barrier plate 60 is connected to an elevating mechanism 61. When the elevating mechanism 61 is operated, the barrier plate 60 moves up and down between an upper position spaced above from the upper surface of a substrate W held by the substrate holder 20 and a lower position closer to the upper surface of the substrate W than the upper position. For example, the elevating mechanism 61 may be a mechanism for converting rotational movements of a motor to translator movements by a ball screw.

The barrier plate 60 has an air outlet 62 that is provided in the center of the lower surface and through which a gas for drying (hereinafter, referred to as the “dry gas”) is issued. The air outlet 62 is connected to a gas supplier (not shown) that supplies the dry gas. The dry gas may, for example, be a heated nitrogen gas.

In the case where the processing fluid is supplied from the top nozzle 41 to a substrate W, the barrier plate 60 retracts to the upper position. In the case where processing for drying a substrate W is performed after the supply of the processing fluid, the elevating mechanism 61 lowers the barrier plate 60 to the lower position. Then, the dry gas is issued from the air outlet 62 toward the upper surface of the substrate W. At this time, the barrier plate 60 prevents diffusion of the gas. As a result, the dry gas is efficiently supplied to the upper surface of the substrate W.

The first to third cameras 71 to 73 are mechanisms for capturing images of a predetermined region within the chamber 10. The region captured by the first to third cameras 71 to 73 is referred to as an “imaging region A.” The first to third cameras 71 to 73 capture moving images that include a predetermined event occurring in the imaging region A. The number of cameras included in the processing unit 102 may be two or four or more.

For example, the first to third cameras 71 to 73 may be installed at positions that are close to the inner surface of the side wall 12 of the chamber 10. As shown in FIG. 2, the first to third cameras 71 to 73 are respectively covered with covers 74 to 76. Accordingly, the first to third cameras 71 to 73 are protected from a processing fluid and gases generated by volatilization of the processing fluid.

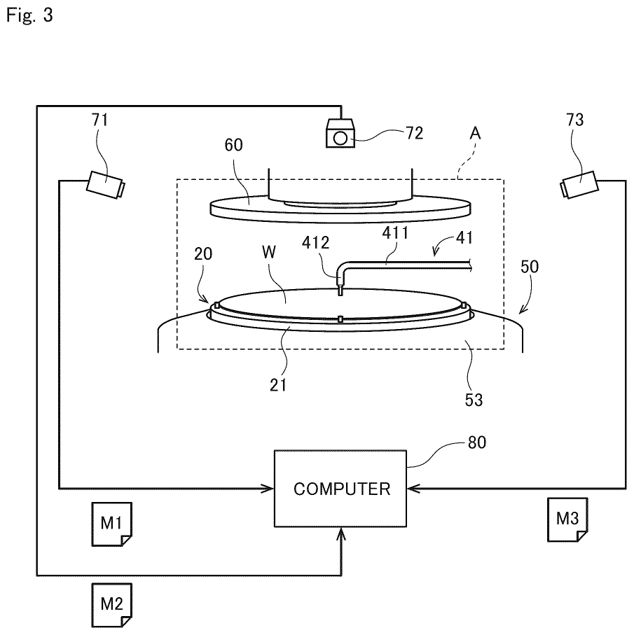

FIG. 3 is a diagram conceptually showing image capture by the first to third cameras 71 to 73 according to a first embodiment which will be described later. In the first embodiment, the first to third cameras 71 to 73 image a move of the nozzle head 412 in a predetermined imaging region A that includes the nozzle head 412.

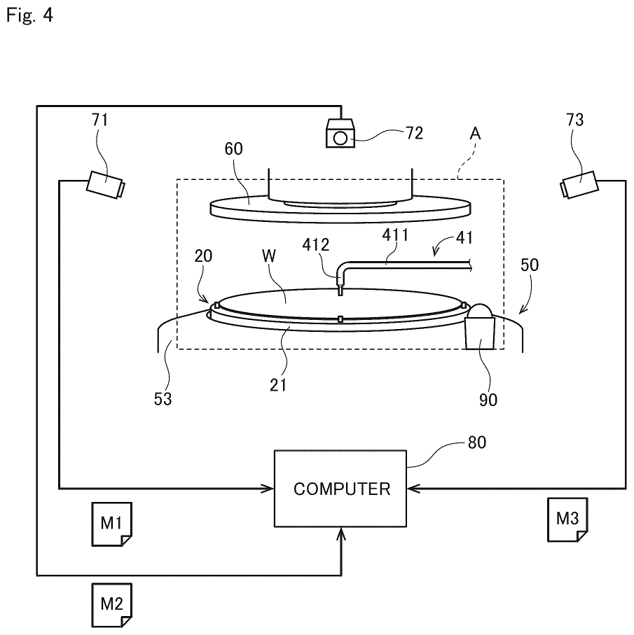

FIG. 4 is a diagram conceptually showing image capture by the first to third cameras 71 to 73 according to a second embodiment which will be described later. In the second embodiment, each processing unit 102 includes a light emitter 90. The light emitter 90 is a mechanism for instantaneously emitting light to the first to third cameras 71 to 73. In the second embodiment, the first to third cameras 71 to 73 each image the light emitted from the light emitter 90.

Note that the light emitter 90 may be or may not be included in the imaging region A as long as moving images captured by the first to third cameras 71 to 73 record a change in the luminance of the imaging region A.

Thus, in both of the first and second embodiments, the first camera 71 captures a first moving image M1, the second camera 72 captures a second moving image M2, and the third camera 73 captures a third moving image M3. Then, the first camera 71 transmits the captured first moving image M1 to the computer 80. The second camera 72 transmits the captured second moving image M2 to the computer 80. The third camera 73 transmits the captured third moving image M3 to the computer 80. Note that the first to third moving images M1 to M3 correspond to “captured image data pieces” according to the present invention.

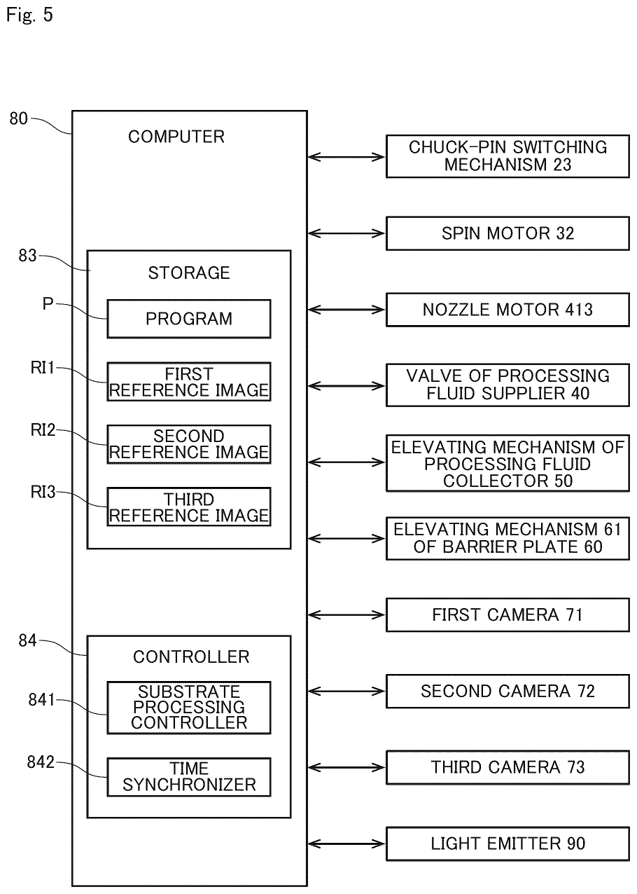

The computer 80 controls operations of each constituent element of the processing units 102. FIG. 5 is a block diagram showing electrical connection between the computer 80 and each constituent element of one processing unit 102. As conceptually shown in FIG. 2, the computer 80 includes a processor 81 such as a CPU, memory 82 such as RAM, and a storage 83 such as a hard disk drive. The computer 80 also includes a controller 84 as conceptually shown in FIG. 5.

As shown in FIG. 5, the computer 80 is communicably connected via a cable or wirelessly to each of the above-described constituent elements including the chuck-pin switching mechanism 23, the spin motor 32, the nozzle motor 413, the valve of the processing fluid supplier 40, the elevating mechanism of the processing fluid collector 50, the elevating mechanism 61 of the barrier plate 60, and the first to third cameras 71 to 73.

The storage 83 stores a program P that is a computer program for controlling the operations of each constituent element of the processing unit 102.

The storage 83 also stores a first reference image RI1, a second reference image RI2, and a third reference image RI3. The first to third reference images RI1 to RI3 are used as references for detecting first to third event images EI1 to EI3 described later by time synchronization processing described later. Details of the first to third reference images RI1 to RI3 will be described later.

The controller 84 is realized by the processor 81 reading out the program P stored in the storage 83, developing the program P in the memory 82, and performing processing in accordance with the program P. The controller 84 includes a substrate processing controller 841 and a time synchronizer 842.

The substrate processing controller 841 performs processing on a substrate W in the processing unit 102. Details of the processing performed on the substrate W in the processing unit 102 will be described later.

The time synchronizer 842 performs time synchronization processing for synchronizing times attached to the first to third moving images M1 to M3. Details of the time synchronization processing will be described later.

After the time synchronization processing is performed by the time synchronizer 842, the controller 84 controls the operations of each constituent element of the processing unit 102 in accordance with the first to third moving images M1 to M3 whose times have been synchronized by the time synchronization processing.

### 3. Operations of Substrate Processing Apparatus

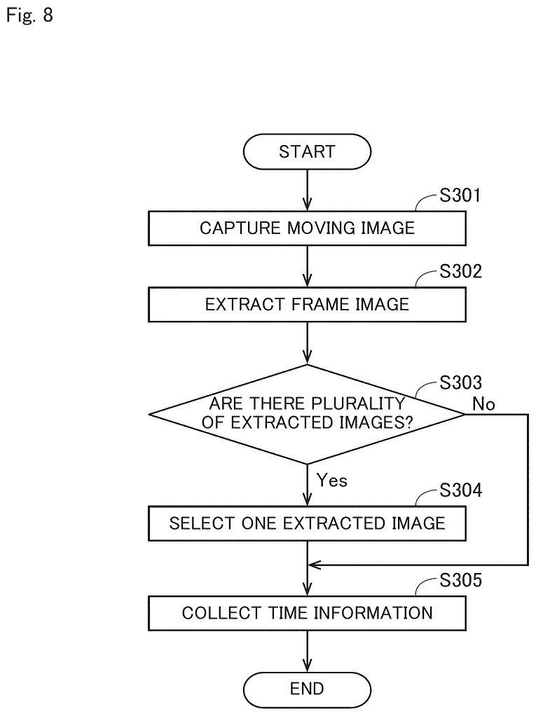

Next description is given of the processing that is performed on a substrate W in the above-described processing unit 102 by the substrate processing controller 841. FIG. 8 is a flowchart showing the procedure of processing that is performed on a substrate W.

In the case of processing a substrate W in the processing unit 102, first, the main transport robot 103 transports the substrate W to be processed into the chamber 10 (step S101). The substrate W transported into the chamber 10 is horizontally held by the chuck pins 22 of the substrate holder 20. After this, the spin motor 32 of the rotation mechanism 30 is driven to start rotation of the substrate W (step S102). Specifically, the substrate W held by the support shaft 33, the spin base 21, and the chuck pins 22 rotate about the shaft center 330 of the support shaft 33.

Then, the processing fluid is supplied from the processing fluid supplier 40 (step S103). In step S3, the nozzle motor 413 is driven so as to move the nozzle head 412 to the processing position facing the upper surface of the substrate W. Then, the processing fluid is ejected from the nozzle head 412 positioned at the processing position. The storage 83 has parameters stored in advance, such as the speed and time of ejection of the processing fluid. The substrate processing controller 841 performs the operation of ejecting the processing fluid from the top nozzle 41 in accordance with the aforementioned settings.

In step S103, the top nozzle 41 may rock in the horizontal direction at the processing position while ejecting the processing fluid. As necessary, a processing fluid may also be ejected from the bottom nozzle 42.

During the process of supplying the processing fluid in step S103, the barrier plate 60 is positioned at the upper position above the top nozzle 41. When the supply of the processing fluid to the substrate W is completed and the top nozzle 41 is positioned at the retracted position, the computer 80 operates the elevating mechanism 61 so as to move the barrier plate 60 from the upper position to the lower position. Then, the number of revolutions of the spin motor 32 is increased to increase the speed of rotation of the substrate W, and the dry gas is issued toward the substrate W from the air outlet 62 provided in the lower surface of the barrier plate 60. In this way, the surface of the substrate W is dried (step S104).

When the processing for drying the substrate W ends, the spin motor 32 is stopped so as to stop the rotation of the substrate W. Then, the hold of the substrate W by the chuck pins 22 is released. Thereafter, the main transport robot 103 takes out the processed substrate W from the substrate holder 20 and transports the processed substrate W to the outside of the chamber 10 (step S105).

Each processing unit 102 repeatedly performs the above-described processing in step S101 to S105 on a plurality of substrates W transported in sequence.

### 4. Time Synchronization Processing

Next, the time synchronization processing performed by the time synchronizer 842 is described. The time synchronization processing is processing for synchronizing the times attached to the first to third moving images M1 to M3 captured by the first to third cameras 71 to 73. Procedures of the time synchronization processing according to first and second embodiments are described hereinafter.

### 4-1. First Embodiment

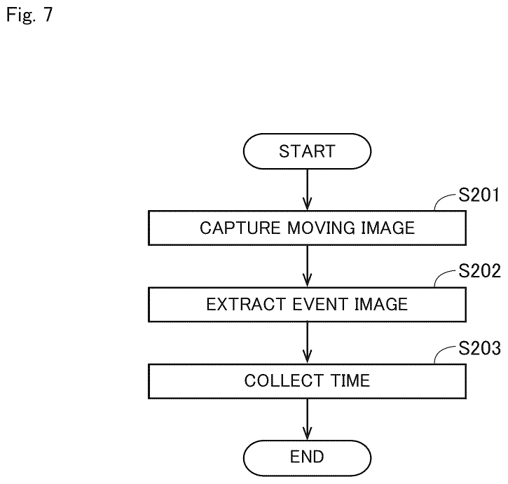

FIG. 7 is a flowchart showing a procedure of the time synchronization processing according to the first embodiment. In the first embodiment, a situation in which the nozzle head 412 has passed through a predetermined location in the imaging region A is defined as an “event.” In the first embodiment, the first to third cameras 71 to 73 capture motion operations of the nozzle head 412 in step S103 to acquire the first to third moving images M1 to M3 (step S201). The motion operation of the nozzle head 412 captured in step S201 does not necessary have to be the operation performed in step S103. For example, the motion operation of the nozzle head 412 may be performed in advance before execution of steps S101 to S105.

The first to third cameras 71 to 73 transmit the acquired the first to third moving images M1 to M3 captured in step S201 to the computer 80. The first to third moving images M1 to M3 transmitted to the computer 80 are stored in the storage 83.

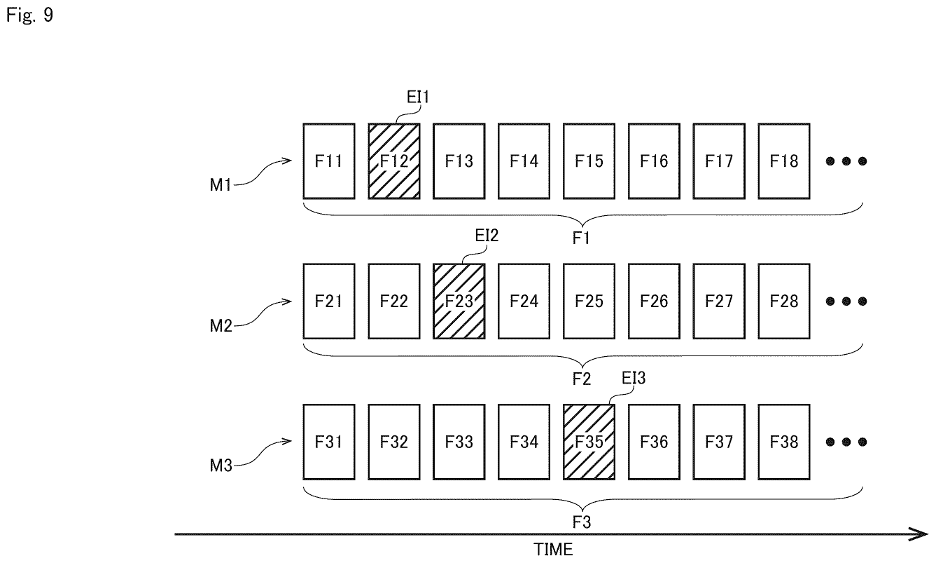

Then, the time synchronizer 842 detects first to third event images EI1 to EI3 respectively from the first to third moving images M1 to M3 stored in the storage 83 (step S202). FIG. 9 is a diagram conceptually showing configurations of the first to third moving images M1 to M3. As shown in FIG. 9, the first moving image M1 is configured by a plurality of frame images F1 (F11, F12, and so on) captured at extremely short time intervals. Similarly, the second moving image M2 is also configured by a plurality of frame images F2 (F21, F22, and so on), and the third moving image M3 is also configured by a plurality of frame images F3 (F31, F32, and so on). Note that the frame images F1 to F3 correspond to “captured images” according to the present invention.

In step S202, the first to third event images EI1 to EI3 are detected from the first to third moving images M1 to M3 on the basis of the first to third reference images RI1 to RI3 stored in the storage 83.

The first to third reference images RI1 to RI3 record the instants at which the nozzle head 412 has passed through a predetermined location in the imaging region A, the instants being defined as an “event” in the first embodiment. Note that the first reference image RI1 is captured within the same imaging range and at the same imaging angle as the first moving image M1. The second reference image RI2 is captured within the same imaging range and at the same imaging angle as the second moving image M2. The third reference image RI3 is captured within the same imaging range and at the same imaging angle as the third moving image M3.

The time synchronizer 842 compares a predetermined region in each of the frame images F1 with that in the first reference image RI1. Then, the time synchronizer 842 detects a frame image F1 that is most similar to the first reference image RI1 as the first event image EI1. In the example shown in FIG. 9, a frame image F12 is detected as the first event image EI1.

Similarly to the first moving image M1, the second and third event images EI2 and EI3 are also detected respectively from the second and third moving images M2 and M3. In the example shown in FIG. 9, a frame image F23 and a frame image F35 are respectively detected as the second event image EI2 and the third event image EI3.

In step S202, the time synchronizer 842 may detect the first to third event images EI1 to EI3 by using a predetermined image processing technique such as an object detection algorithm.

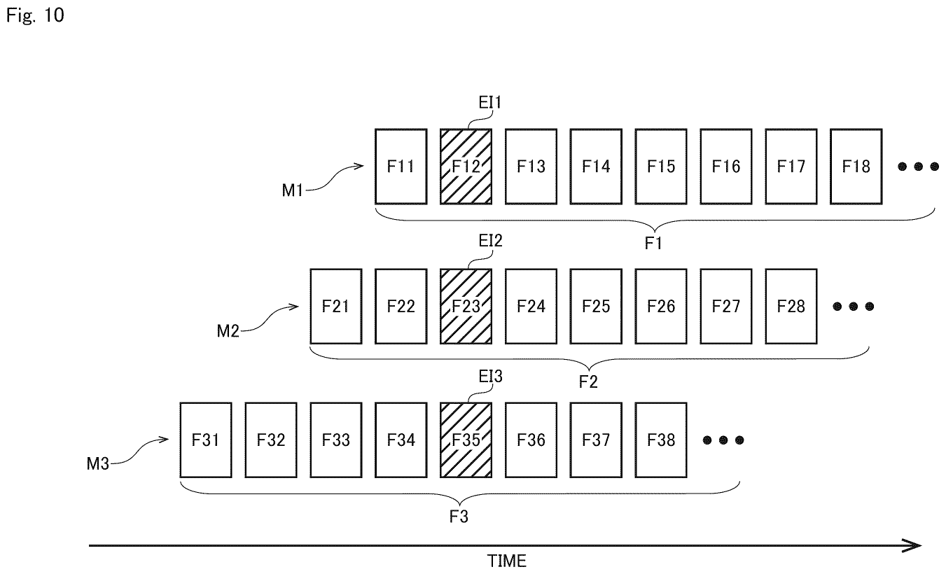

FIG. 10 is a diagram conceptually showing configurations of moving images after correction of the time information. After step S202, the time synchronizer 842 synchronizes the times attached to the first to third moving images M1 to M3 on the basis of the times attached to the first to third event images EI1 to EI3 (step S203). Note that the times attached to the first to third moving images M1 to M3 may, for example, be time information based on the internal clocks of the first to third cameras 71 to 73.

Specifically, firstly, the time synchronizer 842 selects an image with the latest time attached thereto as a reference for time synchronization from among the first to third event images EI1 to EI3. For example, in the example shown in FIG. 9, the time synchronizer 842 selects the third event image EI3 as a reference.

Then, the time synchronizer 842 corrects the times attached to the first and second moving images M1 and M2 such that the times attached to the first and second event images EI1 and E12 coincide with the time attached to the third event image EI3. Accordingly, the times attached to the first to third moving images M1 to M3 are synchronized with one another as shown in FIG. 10.

Nota that each processing unit 102 may repeatedly execute steps S201 to S203 every time the processing unit 102 repeatedly performs step S102 on a plurality of substrates W transported in sequence. Alternatively, the processing for performing steps S201 to S203 after the nozzle head 412 is operated with predetermined timing may be repeatedly performed at predetermined time intervals. This allows the times attached to the first to third moving images M1 to M3 to be synchronized with one another at predetermined time intervals. Accordingly, it is possible to continuously synchronize the times among the first to third moving images M1 to M3.

### 4-2. Second Embodiment

FIG. 8 is a flowchart showing a procedure of the time synchronization processing according to the second embodiment. In the second embodiment, a situation in which the luminance of a predetermined region in the first to third moving images M1 to M3 has reached a predetermined threshold value is defined as an “event.” In the second embodiment, firstly, the first to third cameras 71 to 73 capture moving images in the imaging region A (step S301).

The light emitter 90 instantaneously emits light with arbitrary timing during execution of step S301. Accordingly, the first to third moving images M1 to M3 record the light emitted from the light emitter 90. The first to third cameras 71 to 73 transmit the captured first to third moving images M1 to M3 to the computer 80. The first to third moving images M1 to M3 transmitted to the computer 80 are stored in the storage 83.

Then, the time synchronizer 842 detects the first to third event images EI1 to EI3 respectively from the first to third moving images M1 to M3 stored in the storage 83 (steps S302 to S304).

A specific procedure of steps S302 to S304 is described using the first moving image M1 as an example. Firstly, the time synchronizer 842 extracts images in which the luminance of pixels in a predetermined region are higher than or equal to a predetermined threshold value, from among a plurality of frame images F1 that make up the first moving image M1 (step S302). In the following description, the images extracted in step S302 are referred to as “extracted image.”

In the case where there is only one extracted image (No in step S303), the time synchronizer 842 detects this extracted image as the event image EI.

At this time, a plurality of continuous frame images F1 may be extracted depending on the threshold value or the time of light emission by the light emitter 90. That is, in this case, the first moving image M1 includes a plurality of extracted images that record an event. In the case where there is a plurality of extracted images (Yes in step S303), the time synchronizer 842 selects and detects one of the extracted images as the first event image EI1 (step S304).

For example, the time synchronizer 842 may select the first event image EI1 on the basis of the luminance of the predetermined region in the plurality of extracted images. Specifically, the time synchronizer 842 may select, as the first event image EI1, one extracted image in which a plurality of pixels that make up the predetermined region have a highest average luminance value among the plurality of extracted images.

Alternatively, the time synchronizer 842 may select the first event image EI1 on the basis of the times attached to the extracted images. Specifically, the time synchronizer 842 may select, as the first event image EI1, one extracted image with a time attached thereto that is closest to the average value of the times attached to the plurality of extracted images.

Similarly to the first moving image M1, the time synchronizer 842 also performs steps S302 to S304 on the second and third moving images M2 and M3 in the same manner to extract the second event image EI2 and the third event image EI3.

Then, the time synchronizer 842 synchronizes the times attached to the first to third moving images M1 to M3 with one another on the basis of the times attached to the first to third event images EI1 to EI3 (step S305). The contents of step S305 are similar to the contents of step S203 of the first embodiment, and therefore a description thereof shall be omitted.

Note that the light emitter 90 may emit light periodically at predetermined time intervals. In this case, the time synchronizer 842 periodically performs steps S302 to S305. This allows the times attached to the first to third moving images M1 to M3 to be synchronized with one another at predetermined time intervals. Accordingly, it is possible to continuously synchronize the times among the first to third moving images M1 to M3.

As described above, in the substrate processing apparatus 100, the frame images F1 to F3 that have captured a predetermined event are detected respectively as the event images EI1 to EI3 from the moving images M1 to M3. Then, the times are synchronized among the moving images M1 to M3 on the basis of the times attached to the event images EI1 to EI3 acquired for the moving images M1 to M3. Accordingly, it is possible to synchronize the times among the moving images M1 to M3 without communication between the substrate processing apparatus 100 and an external network.

In the case where a plurality of images that are equivalent to the event images EI1 to EI3 are detected from one moving image M in step S202 of the first embodiment, these detected images may be used as extracted images, and one event image EI1 to EI3 may be detected in the same manner as in step S304 of the second embodiment. Specifically, the time synchronizer 842 may select, as an event image EI1 to EI3, one extracted image with a time attached thereto that is closest to the average value of the times attached to the plurality of images extracted in step S202.

In the second embodiment, the first to third event images EI1 to EI3 may be detected by the same procedure as in step S202 of the first embodiment. In this case, the time synchronizer 842 may detect the first to third event images EI1 to EI3 on the basis of the first to third reference images RI1 to RI3 that record the instants at which the light emitter 90 has emitted light.

### 5. Variations

While embodiments of the present invention have been described thus far, the present invention is not intended to be limited to the embodiments described above.

In the above-described embodiments, the times attached to a plurality of moving images M that have captured the substrate processing apparatus 100 are synchronized with one another. However, the time synchronization method according to the present disclosure is also applicable to various apparatuses. For example, the time synchronization method according to the present disclosure may be applied to a printer. In this case, for example, a situation in which a predetermined resist mark printed on a recording medium has passed through a predetermined location may be defined as an “event.”

In the above-described first embodiment, a situation in which the nozzle arm 411 has passed through a predetermined location in the imaging region A is defined as an “event.” In the above-described second embodiment, a situation in which the luminance of a predetermined region in the first to third moving images M1 to M3 has reached a predetermined threshold value is defined as an “event.” However, the contents of the event are not limited to the definitions described in the above-described embodiments. For example, an event may be a predetermined operation performed by the substrate processing apparatus 100, such as the operation of causing the nozzle head 412 to eject the processing fluid. As another alternative, an event may be a change in the values of pixels in a predetermined region in the first to third moving images M1 to M3 due to a change in coloration or a change in the amount of light emitted from the light emitter 90.

In the above-described embodiments, the first to third cameras 71 to 73 transmit the first to third moving images M1 to M3 to the computer 80 provided in each processing unit 102. Then, the time synchronizer 842 of the computer 80 performs the time synchronization processing. Alternatively, each of the first to third cameras 71 to 73 may include a computer for processing the first to third moving images M1 to M3. Each computer provided in the first to third cameras 71 to 73 may perform steps S201 and S202 of the first embodiment or steps S301 to S304 of the second embodiment on each of the moving images M1 to M3 and then transmit the first to third event images EI1 to EI3 and each of the moving images M1 to M3 to the computer 80. Thereafter, step S203 or S305 may be performed by the time synchronizer 842.

In the above-described embodiments, the first to third cameras 71 to 73 capture the first to third moving images M1 to M3, respectively. Alternatively, the first to third cameras 71 to 73 may intermittently capture a plurality of images at predetermined time intervals. In this case, in the time synchronization processing, the time synchronizer 842 may detect each of the first to third event images EI1 to EI3 from a group of images captured by each of the first to third cameras 71 to 73. Then, the time synchronizer 842 may synchronize the times attached to the group of images with one another on the basis of the times attached to the first to third event images EI1 to EI3.

Each constituent element described in the embodiments and variations described above may be combined appropriately within a range that causes no contradictions.

### REFERENCE SIGNS LIST

40 processing fluid supplier
41 top nozzle
71 first camera
72 second camera
73 third camera
90 light emitter
100 substrate processing apparatus
411 nozzle arm
412 nozzle head
413 nozzle motor
841 substrate processing controller
842 time synchronizer
A imaging region
EI1 first event image
EI2 second event image
EI3 third event image
F1 frame image
F2 frame image
F3 frame image
M1 first moving image
M2 second moving image
M3 third moving image
RI1 first reference image
RI2 second reference image
RI3 third reference image
W substrate

1. A time synchronization method for synchronizing times attached to a plurality of captured image data pieces, the time synchronization method comprising:
a) imaging an object to be imaged by a plurality of cameras to acquire a captured image data piece for each of the cameras, the captured image data piece being included in the plurality of captured image data pieces;
b) detecting, for each of the captured image data pieces, an event image that has captured a predetermined event from the captured image data piece; and
c) synchronizing times attached to the plurality of captured image data pieces in accordance with times attached to the event images detected for the plurality of captured image data pieces.

2. The time synchronization method according to claim 1, wherein
the event corresponds to a situation in which a predetermined portion of the object to be imaged has passed through a predetermined location in an imaging region captured by the plurality of cameras.

3. The time synchronization method according to claim 2, wherein
in the operation b), the event image is detected based on a reference image that serves as a reference during detection.

4. The time synchronization method according to claim 1, wherein
the event corresponds to a situation in which luminance of a predetermined region in the captured image data piece has reached a predetermined threshold value.

5. The time synchronization method according to claim 4, wherein
the operation a) includes emitting light to the imaging region captured by the plurality of cameras with predetermined timing during imaging of the object to be imaged by the plurality of cameras.

6. The time synchronization method according to claim 4, wherein
the operation b) includes:
when one of the captured image data pieces includes one captured image that has captured the event, detecting the one captured image as the event image; and
when one of the captured image data pieces includes a plurality of captured images that have captured the event, detecting one of the plurality of captured images as the event image in accordance with the luminance of each of the plurality of captured images.

7. The time synchronization method according to claim 1, wherein
the operation b) includes:
when one of the captured image data pieces includes one captured image that has captured the event, detecting the one captured image as the event image; and
when one of the captured image data pieces includes a plurality of captured images that have captured the event, detecting one of the plurality of captured images as the event image in accordance with times attached to the plurality of captured images.

8. The time synchronization method according to claim 1, wherein
the captured image data pieces are moving images, and
the event image is a frame included in the moving images.

9. The time synchronization method according to claim 1, wherein
the operations a), b), and c) are repeatedly performed at a predetermined time interval.

10. A manufacturing apparatus for performing processing based on a plurality of captured image data pieces, the manufacturing apparatus comprising:
a plurality of cameras that image an object to be imaged; and
a controller,
wherein the controller:
a) causes the plurality of cameras to image the object to be imaged, to acquire a captured image data piece for each of the cameras, the captured image data piece being included in the plurality of captured image data pieces;
b) detecting, for each of the captured image data pieces, an event image that has captured a predetermined event from a plurality of captured images included in the captured image data piece; and
c) synchronizing times attached to the plurality of captured image data pieces in accordance with times attached to the event images detected for the captured image data pieces.
